(19) United States
(12) Patent Application Publication
(10) Pub. No.: US 2025/0234629 A1
(43) Pub. Date: Jul. 17, 2025

(54) Contact Structures in Semiconductor Devices

(71) Applicant: Taiwan Semiconductor Manufacturing Company, Ltd., Hsinchu (TW)

(72) Inventors: Po-Chin Chang, Taichung City (TW); Min-Hsuan Lu, Hsinchu (TW); Peng-Hsuan Chiang, Hsinchu (TW); Man-Nung Su, Taipei City (TW); Chai-Hung Chu, Taipei City (TW); Tsu Pei Chen, Taipei (TW); Olivia Pei-Hua Lee, Hsinchu (TW); Wei-Yip Loh, Hsinchu (TW); Sung-Li Wang, Hsinchu (TW); Pinyen Lin, Rochester, NY (US)

(73) Assignee: Taiwan Semiconductor Manufacturing Company, Ltd., Hsinchu (TW)

(21) Appl. No.: 18/882,249

(22) Filed: Sep. 11, 2024

Related U.S. Application Data
(60) Provisional application No. 63/620,394, filed on Jan. 12, 2024.

(51) Int. Cl. H01L 29/49; H01L 21/283; H01L 21/3213; H01L 29/06; H01L 29/417; H01L 29/423; H01L 29/775; H01L 29/78; H01L 29/786

(52) U.S. Cl. CPC H10D 64/668; H01L 21/283; H01L 21/32136; H10D 64/254; H10D 30/43; H10D 30/62; H10D 30/6735; H10D 30/6757; H10D 62/121

(57) ABSTRACT

A semiconductor device and a method of fabricating the semiconductor device are disclosed. The semiconductor device includes a substrate, first and second source/drain (S/D) regions disposed on the substrate, and a contact structure. The contact structure includes first and second conductive capping layers disposed on the first and second S/D regions, and a conductive plug. The conductive plug includes a first plug portion disposed on top surfaces of the first and second conductive capping layers, a second plug portion disposed between the first and second conductive capping layers, and a third plug portion disposed between the first and second S/D regions.

### CROSS-REFERENCE TO RELATED APPLICATIONS

This application claims the benefit of U.S. Provisional Patent Application No. 63/620,394, titled “Metal Contact on Source/Drain Region without Metal Oxide therebetween,” filed Jan. 12, 2024, which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1 illustrates an isometric view of a semiconductor device, in accordance with some embodiments.

FIGS. 2A, 2B, 4, and 5 illustrate different cross-sectional views of a semiconductor device with contact structures, in accordance with some embodiments.

FIG. 3 illustrates a fluorine concentration profile in a contact structure of a semiconductor device, in accordance with some embodiments.

FIG. 6 is a flow diagram of a method for fabricating a semiconductor device with a contact structure, in accordance with some embodiments.

FIGS. 7A-20A and 7B-20B illustrate cross-sectional views of a semiconductor device with a contact structure at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

The GAA transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

The present disclosure provides example methods for minimizing contact resistance between contact structures and source/drain (S/D) regions in FETs (e.g., finFETs and GAA FETs). In some embodiments, a S/D region can be formed on a fin structure and a contact structure can be formed on the S/D region. In some embodiments, the formation of the contact structure can include forming a silicide layer in a contact opening on the S/D region, performing a cleaning process on the silicide layer, depositing a conductive capping layer on the silicide layer, and depositing a conductive plug on the conductive capping layer. The formation of the silicide layer, the cleaning process, the deposition of the conductive capping layer and the conductive plug can be performed in an in-situ process in a cluster tool system. The cleaning process can remove a native metal oxide layer, a native metal oxynitride layer, and/or oxygen atoms from a top surface of the silicide layer to reduce a concentration of oxygen atoms on the top surface of the silicide layer to less than about 5 atomic % (e.g., about zero atomic % to about 4.9 atomic %). The native metal oxide layer, the native metal oxynitride layer, and/or the oxygen atoms on the top surface of the silicide layer can be introduced due to a reaction between oxygen and the silicide layer when switching process chambers between the formation of the silicide layer and the deposition of the conductive capping layer. The presence of the native metal oxide layer, the native metal oxynitride layer, and/or the oxygen atoms at the interface between the silicide layer and the conductive capping layer can degrade the electrical conductivity between the contact structure and the S/D region. Thus, the cleaning process can minimize the contact resistance between the contact structure and the S/D region.

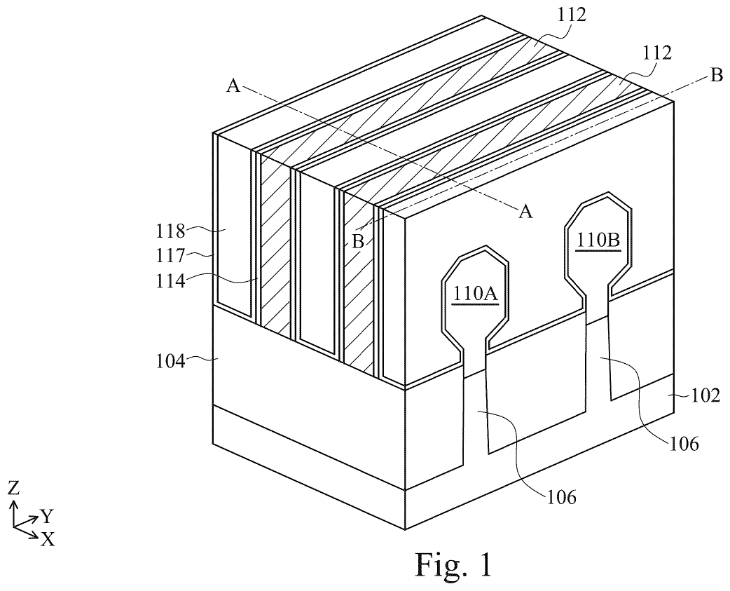

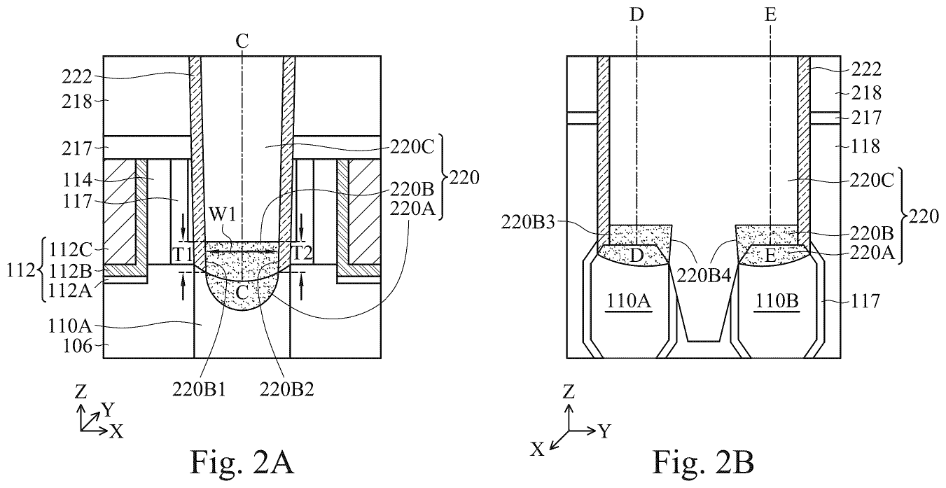

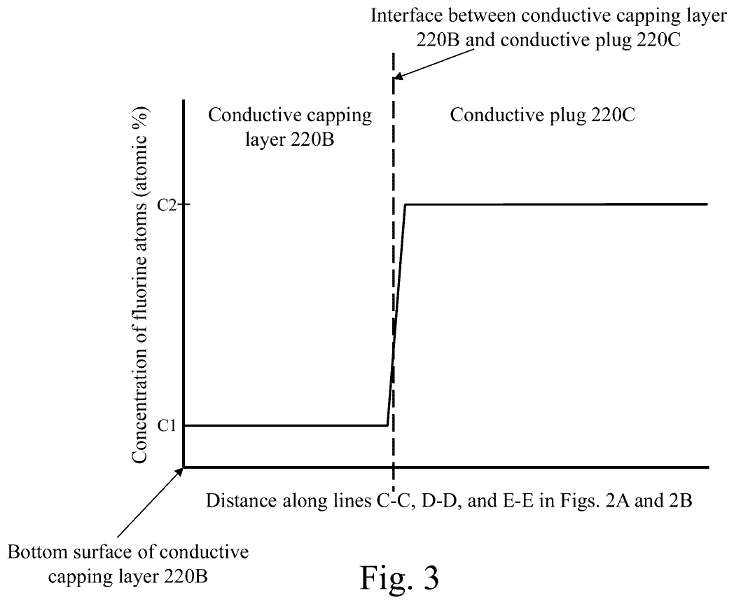

FIG. 1 illustrates an isometric view of a semiconductor device 100, which can represent a finFET 100, according to some embodiments. FIG. 2A illustrate a cross-sectional view of finFET 100, along line A-A of FIG. 1, with additional structures that are not shown in FIG. 1 for simplicity, according to some embodiments. FIG. 2B illustrates a cross-sectional view of finFET 100 along line B-B of FIG. 1 with additional structures that are not shown in FIG. 1 for simplicity, according to some embodiments. FIG. 3 illustrates a fluorine concentration profile along line C-C of FIGS. 2A and 2B, according to some embodiments. The discussion of elements in FIGS. 1, 2A, 2B, and 3-5 with the same annotations applies to each other, unless mentioned otherwise.

Referring to FIGS. 1, 2A, and 2B, in some embodiments, finFET 100 can include (i) a substrate 102, (ii) shallow trench isolation (STI) regions 104 disposed on substrate 102, (iii) fin structures 106 disposed on substrate 102, (iv) S/D regions 110A and 110B disposed on fin structures 106, (v) gate structures 112 disposed on fin structures 106, (vi) gate spacers 114 disposed along sidewalls of gate structures 112, (vii) etch stop layer (ESL) 117 disposed directly on S/D regions 110A and 110B, (viii) interlayer dielectric (ILD) layer 118 disposed directly on ESL 117, (ix) ESL 217 disposed on gate structures 112, gate spacers 114, ESL 117, and ILD layer 118, (x) ILD layer 218 disposed on ESL 217, (xi) contact structures 220 disposed directly on S/D regions 110A and 110B, and (xii) barrier layers 222 disposed along sidewalls of contact structures 220.

In some embodiments, substrate 102 can be a semiconductor material, such as silicon (Si), germanium (Ge), silicon germanium (SiGe), a silicon-on-insulator (SOI) structure, and a combination thereof. Further, substrate 102 can be doped with p-type dopants (e.g., boron, indium, aluminum, or gallium) or n-type dopants (e.g., phosphorus or arsenic). In some embodiments, STI regions 104 can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), and silicon germanium oxide (SiGeOₓ). In some embodiments, fin structures 106 can include a material similar to substrate 102. Fin structures 106 can have elongated sides extending along an X-axis.

In some embodiments, S/D regions 110A and 110B can include an epitaxially- grown semiconductor material, such as Si, and n-type dopants, such as phosphorus and other suitable n-type dopants for n-type finFET 100. S/D regions 110A and 110B can include an epitaxially-grown semiconductor material, such as Si and SiGe, and p-type dopants, such as boron and other suitable p-type dopants for p-type finFET 100. Each of S/D regions 110A and 110B may refer to a source or a drain, individually or collectively dependent upon the context.

In some embodiments, each of gate structures 112 can be a multi-layered structure and can include (i) an interfacial oxide (IL) layer 112A, (ii) a high-k (HK) gate dielectric layer 112B, and (iii) a conductive layer 112C. In some embodiments, IL layer 112A can be disposed directly on fin structure 106. In some embodiments, IL layer 112A can include SiO₂, SiGeOx, or germanium oxide (GeOₓ) and can have a thickness H1 of about 0.5 nm to about 1 nm. In some embodiments, HK gate dielectric layer 112B can be disposed directly on IL layer 112A and can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). In some embodiments, the sidewalls of HK gate dielectric layer 112B can be in contact with sidewalls of gate spacers 114.

In some embodiments, conductive layer 112C can be disposed on HK gate dielectric layer 112B and can be multi-layered structures. The different layers of conductive layer 112C are not shown for simplicity. In some embodiments, conductive layer 112C can include a work function metal (WFM) layer disposed on HK gate dielectric layer 112B and a gate metal fill layer disposed on the WFM layer. In some embodiments, the WFM layer can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu) for p-type finFET 100. In some embodiments, the WFM layer can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials for n-type finFET 100. In some embodiments, the gate metal fill layer can include a suitable conductive material, such as tungsten (W), titanium (Ti), silver (Ag), ruthenium (Ru), molybdenum (Mo), copper (Cu), cobalt (Co), Al, iridium (Ir), nickel (Ni), metal alloys, and a combination thereof.

Gate spacers 114 can electrically isolate gate structures 112 from adjacent S/D regions 110A and 110B, and from adjacent contact structures 220. In some embodiments, gate spacers 114 can include a dielectric material, such as SiO₂, SiN, SiON, SiOC, SiCN, SiOCN, and any other suitable dielectric material. In some embodiments, ESLs 117, ILD layer 118, ESL 217, and ILD layer 218 can include a dielectric material, such as SiO₂, SiN, SiON, SiOC, SiCN, and SiOCN.

In some embodiments, contact structure 220 can include (i) a silicide layer 220A, (ii) a conductive capping layer 220B disposed on silicide layer 220A, and (iii) a conductive plug 220C disposed on conductive capping layer 220B. In some embodiments, silicide layer 220A in n-type finFET 100 can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ybtterbium silicide (YbₓSi_{y}), europium silicide (EuₓSi_{y}), thorium silicide (ThₓSi_{y}), other suitable metal silicide materials, or a combination thereof. In some embodiments, silicide layer 220A in p-type finFET 100 can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), other suitable metal silicide materials, or a combination thereof. In some embodiments, silicide layer 220A can have a thickness of about 1 nm to about 20 nm along a Z-axis to provide adequate conductive interface between contact structure 220 and S/D regions 110A and 110B.

In some embodiments, conductive capping layers 220B can be disposed directly on silicide layers 220A. In some embodiments, a cross-sectional profile of conductive capping layer 220B along an X-axis can have (i) first and second sidewalls 220B1 and 220B2 of conductive capping layer 220B in contact with barrier layer 222, (ii) a thickness at the center of conductive capping layer 220B greater than thicknesses along first and second sidewalls 220B1 and 220B2 of conductive capping layer 220B, (iii) thicknesses T1 and T2 of about 1 nm to about 5 nm along first sidewall 220B1 and second sidewall 220B2, respectively, (iv) a bottom surface with a curved profile in contact with silicide layer 220A, and (v) a width W1 of about 1 nm to about 38 nm.

In some embodiments, a cross-sectional profile of conductive capping layer 220B along a Y-axis can have (i) a third sidewall 220B3 of conductive capping layer 220B in contact with barrier layer 222, (ii) a fourth sidewall 220B4 of conductive capping layer 220B in contact with conductive plug 220C, (iii) a thickness along fourth sidewall 220B4 of conductive capping layer 220B greater than the thickness at the center of conductive capping layer 220B and/or a thickness along third sidewall 220B3 of conductive capping layer 220B, (iv) a first bottom surface portion with a substantially linear profile in contact with a top surface of silicide layer 220A, and (v) a second bottom surface portion with a sloped profile in contact with a sloped sidewall of silicide layer 220A. In some embodiments, as conductive capping layers 220B are formed selectively on silicide layers 220A, conductive capping layers 220B may not be in contact with portions of ESL 117 and ILD layer 118 underlying conductive capping layers 220B, as shown in FIG. 2B.

In some embodiments, the interface between conductive capping layer 220B and silicide layer 220A can be substantially oxygen-free and can have a concentration of oxygen atoms less than about 1 atomic % (e.g., about zero atomic % to about 0.9 atomic %). As discussed below, a cleaning process is performed on silicide layers 220A prior to forming conductive capping layers 220B to remove oxygen atoms from top surfaces and sidewalls of silicide layers 220A. The substantially oxygen-free interface minimizes contact resistance between contact structure 220 and S/D regions 110A and 110B, thus improving device performance. In some embodiments, conductive capping layer 220B can include a conductive material, such as W, Ru, and Mo. In some embodiments, the conductive material of conductive capping layer 220B can be fluorine-free or can have a concentration of fluorine atoms less than about 5 atomic % (e.g., about zero atomic % to about 4.9 atomic %). With the use of fluorine-free conductive capping layer 220B, damages to silicide layers 220A from fluorine atoms can be prevented or minimized.

In some embodiments, conductive plug 220C can be disposed directly on conductive capping layers 220B and between S/D regions 110A and 110B, as shown in FIG. 2B. In some embodiments, a cross-sectional profile of conductive plug 220C along an X-axis can have (i) a top surface with a width of about 2 nm to about 40 nm, and (ii) a bottom surface with a width of about 1 nm to about 39 nm. In some embodiments, a cross-sectional profile of conductive plug 220C along a Y-axis can have (i) a first portion disposed directly on conductive capping layers 220B, (ii) a second portion disposed between and in contact with fourth sidewalls 220B4 of conductive capping layers 220B on S/D regions 110A and 110B, (iii) a third portion with sloped sidewalls and substantially linear bottom surface disposed between S/D regions 110A and 110B and on ILD layer 118, (iv) the sloped sidewalls of third portion in contact with ESLs 117 on S/D regions 110A and 110B and with ILD layer 118, and (v) the third portion extending below top surfaces of S/D regions 110A and 110B.

In some embodiments, conductive plug 220C can include a conductive material, such as Co, W, Ru, Al, Mo, Ir, Ni, Osmium (Os), rhodium (Rh), other suitable conductive materials, and a combination thereof. In some embodiments, conductive capping layer 220B and conductive plug 220C can have the same or different conductive materials, but with different fluorine concentrations. In some embodiments, conductive plug 220C can have a fluorine concentration C2 higher than a fluorine concentration C1 of conductive capping layer 220B, as shown in FIG. 3. FIG. 3 shows the fluorine concentration along line C-C of FIG. 2A and along lines D-D and E-E of FIG. 2B. In some embodiments, fluorine concentration C2 in conductive plug 220C can be greater than about 5 atomic % (e.g., about 6 atomic % to about 20 atomic %) and fluorine concentration C1 in conductive capping layer 220B can be less than about 5 atomic % (e.g., about zero atomic % to about 4.9 atomic %). In some embodiments, conductive capping layer 220B can have a fluorine-free W layer, a fluorine-free Ru layer, or a fluorine-free Mo layer when conductive plug 220C has a fluorine-doped W layer. In some embodiments, conductive capping layer 220B can have a fluorine-free W layer when conductive plug 220C has a fluorine-doped W layer, a fluorine-doped Ru layer, or a fluorine-doped Mo layer. In some embodiments, conductive capping layer 220B can have a fluorine-free W layer when conductive plug 220C has a fluorine-free Ru layer or a fluorine-free Mo layer.

In some embodiments, contact structure 220 can be surrounded by barrier layer 222 and can be configured to prevent or minimize the diffusion of oxygen atoms from ILD layers 118 and 218 into conductive capping layer 220B and/or conductive plug 220C. Barrier layer 222 can also be configured to prevent or minimize the diffusion of metal atoms from conductive capping layer 220B and/or conductive plug 220C into gate structures 112. In some embodiments, barrier layer 222 can include oxygen-free dielectric nitride layers (e.g., SiN layers), oxygen-free dielectric carbide layers (e.g., silicon carbide (SiC) layers), or oxygen-free carbon nitride layers (e.g., silicon carbon nitride (SiCN) layers). In some embodiments, barrier layer 222 can have a thickness of about 2 nm to about 9 nm along an X-axis to adequately prevent or minimize (i) the diffusion of oxygen atoms from ILD layers 118 and 218 into conductive capping layer 220B and/or conductive plug 220C, and (ii) the diffusion of metal atoms from conductive capping layer 220B and/or conductive plug 220C into gate structures 112.

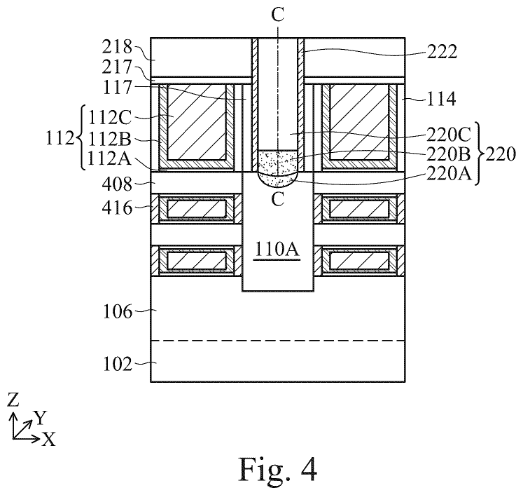

In some embodiments, semiconductor device 100 can represent a GAA FET 100, instead of finFET 100 and can have a cross-sectional view of FIG. 4 across line A-A of FIG. 1 with additional structures that are not shown in FIG. 1 for simplicity. In some embodiments, the cross-sectional view of GAA FET 100 across line B-B of FIG. 1 can be the same as the cross-sectional view of FIG. 2B. The discussion of elements in FIGS. 1, 2A, 2B, 3, and 4 with the same annotations applies to each other, unless mentioned otherwise. Referring to FIG. 4, unlike finFET 100, GAA FET 100 can have (i) base structures 106, (ii) nanostructured channel regions 408 disposed on base structures 106, (ii) gate structures 112 with a cross-sectional view as shown in FIG. 4, instead of the cross-sectional view shown in FIG. 2A, and (iii) inner spacers 416. Base structures 106 can include a material similar to substrate 102.

Gate structures 112 of GAA FET 100 can be wrapped around nanostructured channel regions 408 and can be electrically isolated from adjacent S/D regions 110 by inner spacers 416. Gate structures 112 of GAA FET 100 can be referred to as GAA structures 112. In some embodiments, nanostructured channel regions 408 can be in the form of nanosheets, nanowires, nanorods, nanotubes, or other suitable nanostructured shapes. As used herein, the term “nanostructured” defines a structure, layer, and/or region as having a horizontal dimension (e.g., along an X-and/or Y-axis) and/or a vertical dimension (e.g., along a Z-axis) less than about 100 nm, for example about 90 nm, about 50 nm, about 10 nm, or other values less than about 100 nm. Nanostructured channel regions 408 can include semiconductor materials similar to or different from substrate 102. In some embodiments, nanostructured channel regions 408 can include Si, silicon arsenide (SiAs), silicon phosphide (SiP), silicon carbide (SiC), silicon carbon phosphide (SiCP), silicon germanium (SiGe), silicon germanium boron (SiGeB), germanium boron (GeB), silicon germanium stannum boron (SiGeSnB), a III-V semiconductor compound, or other suitable semiconductor materials. In some embodiments, each of nanostructured channel regions 408 can have a thickness of about 3 nm to about 15 nm along a Z-axis. Though two nanostructured channel regions 408 are shown under each of gate structures 112, GAA FET 100 can have any number of nanostructured channel regions 408. Though rectangular cross-sections of nanostructured channel regions 408 are shown, nanostructured channel regions 408 can have cross-sections with other geometric shapes (e.g., circular, elliptical, triangular, or polygonal).

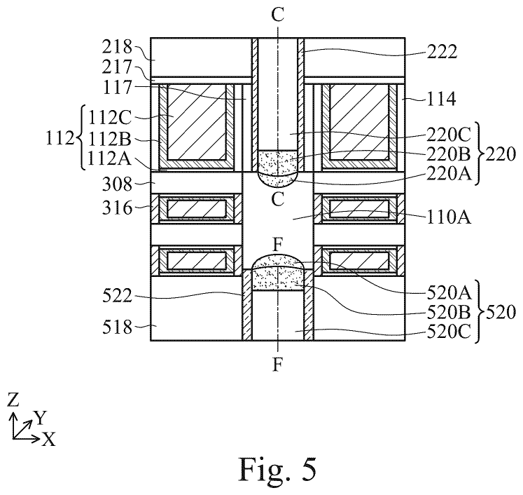

In some embodiments, GAA FET 100 can have a cross-sectional view of FIG. 5 across line A-A of FIG. 1, instead of the cross-sectional view of FIG. 4, with additional structures that are not shown in FIG. 1 for simplicity. The discussion of elements in FIGS. 1, 2A, 2B, 3, 4, and 5 with the same annotations applies to each other, unless mentioned otherwise. Referring to FIG. 5, unlike GAA FET 100 of FIG. 4, GAA FET 100 of FIG. 5 can have (i) a back-side ILD layer 518, instead of substrate 102 and base structures 106, (ii) a back-side contact structure 520, and (iii) a back-side barrier layer 522. In some embodiments, back-side ILD layer 518 can be disposed on the back sides of GAA structures 112 and S/D regions 110A and 110B (S/D region 110B not visible in the cross-sectional view of FIG. 5). In some embodiments, back-side contact structure 520 can be disposed in back-side ILD layer 518 and on the back side of S/D region 110A. Similar to contact structure 220, contact structure 520 can include (i) a silicide layer 520A, (ii) a conductive capping layer 520B, and (iii) a conductive plug 520C. The discussion of silicide layers 220A, conductive capping layers 220B, and conductive plug 220C applies to silicide layer 520A, conductive capping layer 520B, and conductive plug 520C, unless mentioned otherwise. In some embodiments, silicide layer 520A and conductive capping layer 520B can be disposed on the back side of S/D region 110A and may not be disposed on the back side of S/D region 110B. In some embodiments, conductive plug 520C can be disposed on conductive capping layer 520B and may not be disposed on sidewalls of S/D region 110A and between S/D regions 110A and 110B. In some embodiments, the cross-sectional view of contact structure 520 on the back sides of S/D regions 110A and 110B across line F-F of FIG. 5 can be the same as the cross-sectional view of contact structure 220 on the front sides of S/D regions 110A and 110B shown in FIG. 2B. In some embodiments, contact structure 520 can have the same fluorine concentration profile across line F-F of FIG. 5 as the fluorine concentration profile across line C-C of FIG. 3.

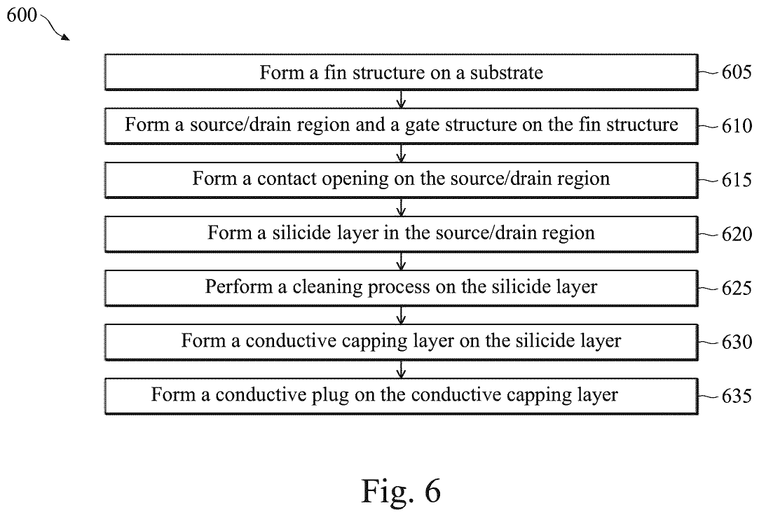

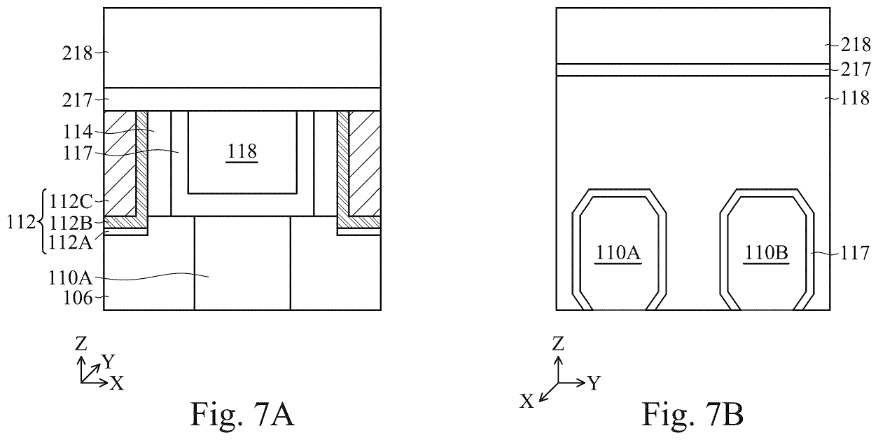

FIG. 6 is a flow diagram of an example method 600 for fabricating semiconductor device 100 with the cross-sectional views of FIGS. 1, 2A, and 2B, according to some embodiments. For illustrative purposes, the operations illustrated in FIG. 6 will be described with reference to the example fabrication process for fabricating semiconductor device 100 as illustrated in FIGS. 1, 7A-20A, and 7B-20B. FIGS. 7A-20A are cross-sectional views of semiconductor device 100 along line A-A of FIG. 1 at various stages of fabrication of semiconductor device 100, according to some embodiments. FIGS. 7B-20B are cross-sectional views of semiconductor device 100 along line B-B of FIG. 1 at various stages of fabrication of semiconductor device 100, according to some embodiments. Operations can be performed in a different order or not performed depending on specific applications. It should be noted that method 600 may not produce a complete semiconductor device 100. Accordingly, it is understood that additional processes can be provided before, during, and after method 600, and that some other processes may only be briefly described herein. The discussion of elements in FIGS. 1, 2A, and 2B, 7A-20A, and 7B-20B with the same annotations applies to each other, unless mentioned otherwise.

Referring to FIG. 6, in operation 605, a fin structure is formed on a substrate. For example, as described with reference to FIGS. 1 and 7A, fin structures 106 are formed on substrate 102 (not visible in the cross-sectional view of FIG. 7B). In some embodiments, the formation of fin structures 106 can include patterning substrate 102 using one or more photolithography processes, including double-patterning or multi-patterning processes.

Referring to FIG. 6, in operation 610, a S/D region and a gate structure is formed on the fin structure. For example, as described with reference to FIGS. 7A and 7B, S/D regions 110A and 110B, and gate structures 112 are formed on fin structure 106. In some embodiments, the formation of S/D regions 110A and 110B can include sequential operations of (i) etching portions of fin structures 106 to form S/D openings (not shown); and (ii) epitaxially growing a semiconductor material (e.g., Si or SiGe) with n-type or p-type dopants in the S/D openings. In some embodiments, the formation of gate structures 112 can include sequential operations of (i) forming polysilicon structures (not shown) on fin structures 106 prior to forming S/D regions 110A and 110B; and (ii) replacing the polysilicon structures with gate structures 112 after forming S/D regions 110A and 110B. The formation of S/D regions 110A and 110B can be followed by the formation of ESLs 117, ILD layer 118, ESLs 217, and ILD layer 218, as shown in FIGS. 7A and 7B.

The following operations 615-635 describes the formation of contact structures 220 on S/D regions 110A and 110B.

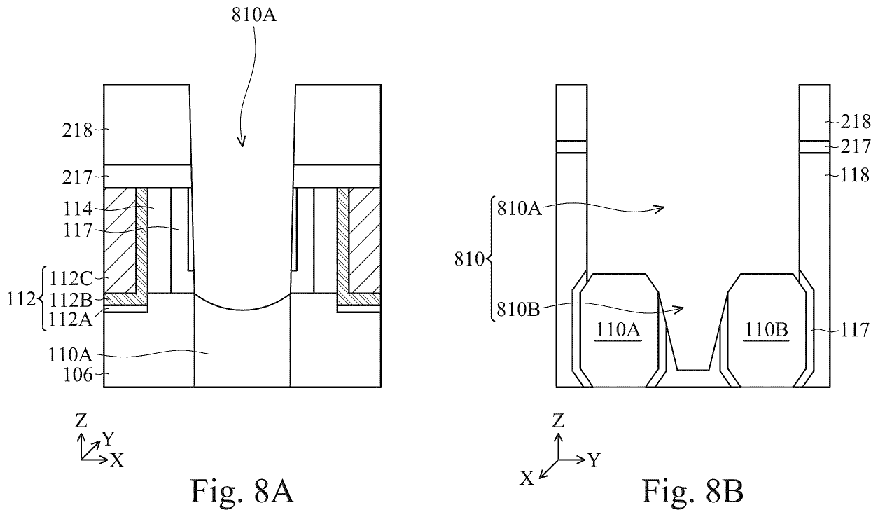

Referring to FIG. 6, in operation 615, a contact opening is formed on the S/D regions. For examples, as described with reference to FIGS. 8A and 8B, a contact opening 810 having openings 810A and 810B are formed. Opening 810A is formed on S/D regions 110A and 110B and opening 810B (not visible in the cross-sectional view of FIG. 8A) is formed between S/D regions 110A and 110B. In some embodiments, the formation of contact opening 810 can include sequential operations of (i) etching portions of ESL 117, ILD layer 118, ESL 217, and ILD layer 218 on S/D regions 110A and 110B to form opening 810A, as shown in FIGS. 8A and 8B, and (ii) etching portions of ESL 117 and ILD layer 118 between S/D regions 110A and 110B to form opening 810B, as shown in FIG. 8B. Opening 810A can expose top surfaces of S/D regions 110A and 110B and sidewalls of ESL 117, ILD layer 118, ESL 217, and ILD layer 218. Opening 810B can expose surfaces of S/D regions 110A and 110B facing each other, and surfaces of ESL 117 and ILD layer 118 between S/D regions 110A and 110B. In some embodiments, opening 810B can have a cross-sectional profile with sloped sidewalls along a Y-axis.

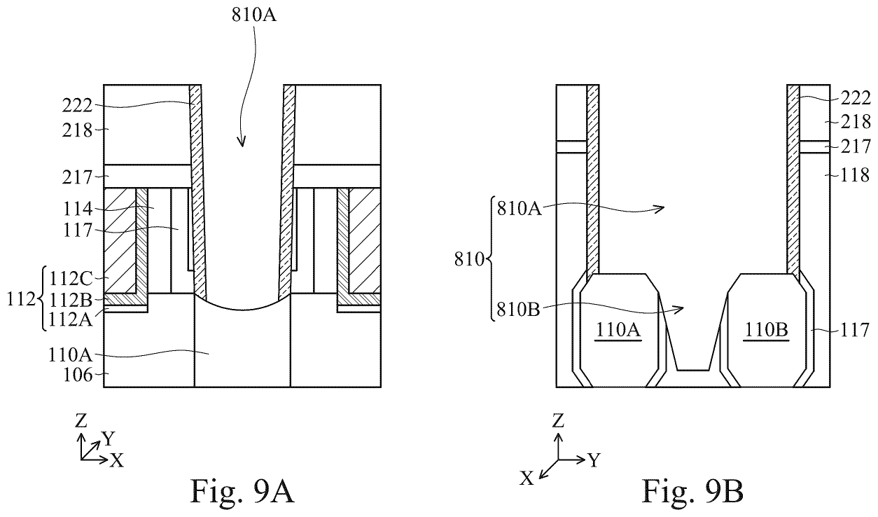

In some embodiments, the formation of contact opening 810 can be followed by the formation of barrier layer 222 along sidewalls of opening 810A, as shown in FIGS. 9A and 9B. The formation of barrier layer 222 can include sequential operations of (i) depositing an oxygen-free dielectric layer (not shown), such as an oxygen-free dielectric nitride layer (e.g., SiN layer), an oxygen-free dielectric carbide layer (e.g., SiC layer), and an oxygen-free carbon nitride layer (e.g., SiCN layer) on the structures of FIGS. 8A and 8B, and (ii) removing portions of the oxygen-free dielectric layer from a top surface of ILD layer 218, from top surfaces of S/D regions 110A and 110B, and from surfaces of ESL 117 and ILD layer 118 in opening 810B to form the structures of FIGS. 9A and 9B.

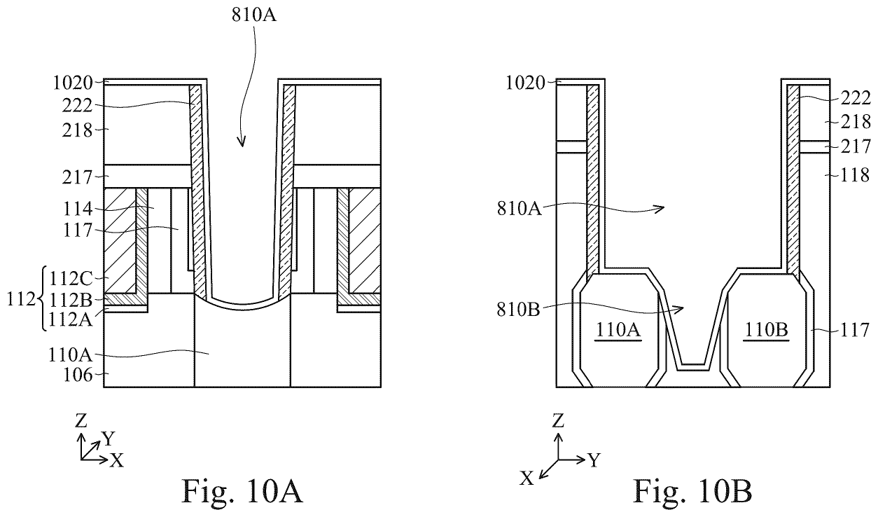

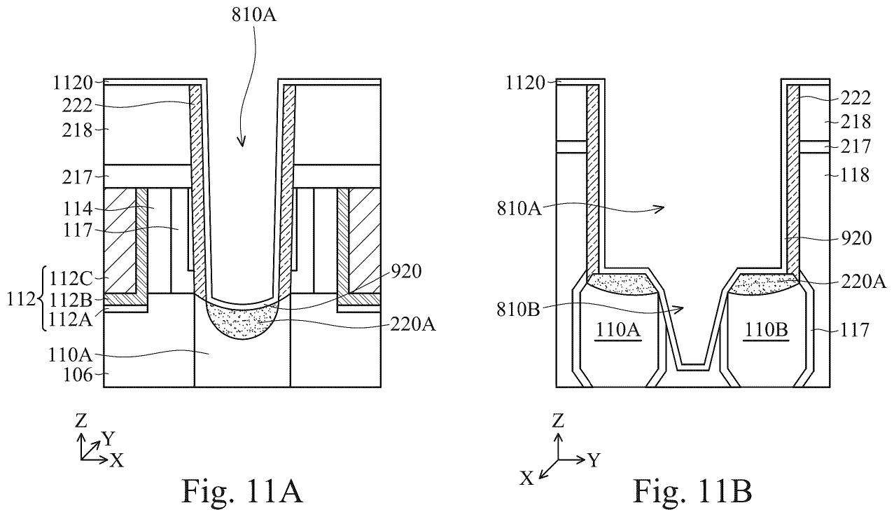

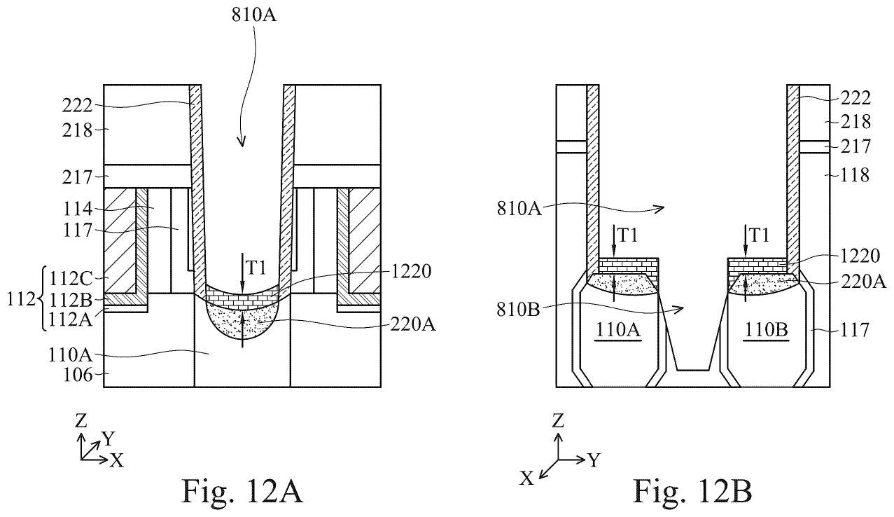

Referring to FIG. 6, in operation 620, a silicide layer is formed in the S/D region. For example, as described with reference to FIGS. 10A-12A and 10B-12B, silicide layers 220A are formed in S/D regions 110A and 110B. In some embodiments, the formation of silicide layers 220A can include sequential operations of (i) depositing a metal layer 1020 using a chemical vapor deposition (CVD) process or an atomic layer deposition (ALD) process on the structures of FIGS. 9A and 9B to form the structures of FIGS. 10A and 10B, (ii) performing an anneal process on metal layer 1020 to initiate a silicidation reaction between the metal of metal layer 1020 and the semiconductor (e.g., Si or SiGe) of S/D regions 110A and 110B to form silicide layers 220A, as shown in FIGS. 11A and 11B, and (iii) removing (e.g., etching) unreacted metal layer 1120 from the structures of FIGS. 11A and 11B to form the structures of FIGS. 12A and 12B. The unreacted metal layer 1120 is a portion of metal layer 1020 that did not react with the semiconductor of S/D regions 110A and 110B. In some embodiments, metal layer 1020 can include a titanium (Ti) layer, a tantalum (Ta) layer, a molybdenum (Mo) layer, a zirconium (Zr) layer, a scandium (Sc) layer, a yttrium (Y) layer, a terbium (Tb) layer, a cobalt (Co) layer, a tungsten (W) layer, an iron (Fe) layer, a rhodium (Rh) layer, a palladium (Pd) layer, a ruthenium (Ru) layer, a platinum (Pt) layer, an iridium (Ir) layer, or an osmium (Os) layer.

During and/or after the removal of unreacted metal layer 1120, native layers 1220 (e.g., native metal oxide layers 1220 or native metal oxynitride layers 1220) can be formed on silicide layers 220A, as shown in FIGS. 12A and 12B. In some embodiments, native layers 1220 can be formed when switching process chambers between the formation of silicide layers 220A and the formation of conductive capping layer 220B in operation 630. In some embodiments, native metal oxide layer 1220 can be formed due to a reaction between oxygen and silicide layers 220A. In some embodiments, native metal oxynitride layer 1220 can be formed due to a reaction among oxygen, silicide layers 220A, and barrier layer 222.

In some embodiments, native metal oxide layers 1220 can include a metal of metal layer 1020. In some embodiments, native metal oxide layers 1220 can include titanium silicon oxide (TiSiOₓ), tantalum silicon oxide (TaSiOₓ), molybdenum silicon oxide (MoSiOₓ), zirconium silicon oxide (ZrSiOx), scandium silicon oxide (ScSiOx), yttrium silicon oxide (YSiOₓ), terbium silicon oxide (TbSiOₓ), cobalt silicon oxide (CoSiOₓ), tungsten silicon oxide (WSiOₓ), iron silicon oxide (FeSiOₓ), rhodium silicon oxide (RhSiₓOₓ), palladium silicon oxide (PdSiₓOₓ), ruthenium silicon oxide (RuSiₓOₓ), platinum silicon oxide (PtSiₓOₓ), iridium silicon oxide (IrSiₓOₓ), or osmium silicon oxide (OsSiₓOₓ). In some embodiments, native metal oxynitride layers 1220 can include a metal of metal layer 1020. In some embodiments, native metal oxynitride layers 1220 can include titanium oxynitride (TiSiOₓN_{y}), tantalum oxynitride (TaSiOₓN_{y}), molybdenum oxynitride (MoSiOₓN_{y}), zirconium oxynitride (ZrSiOₓN_{y}), scandium oxynitride (ScSiOₓN_{y}), yttrium oxynitride (YSiOₓN_{y}), terbium oxynitride (TbSiOₓN_{y}), cobalt oxynitride (CoSiOₓN_{y}), tungsten oxynitride (WSiOₓN_{y}), iron oxynitride (FeSiOₓN_{y}), rhodium oxynitride (RhSiOₓN_{y}), palladium oxynitride (PdSiOₓN_{y}), ruthenium oxynitride (RuSiOₓN_{y}), platinum oxynitride (PtSiOₓN_{y}), iridium oxynitride (IrSiOₓN_{y}), or osmium oxynitride (OsSiOₓN_{y}).

As the presence of native layers 1220 increases the contact resistance between contact structures 220 and S/D regions 110A and 110B, native layers 1220 are removed in subsequent operation 625 prior to forming conductive capping layer 220B in operation 630.

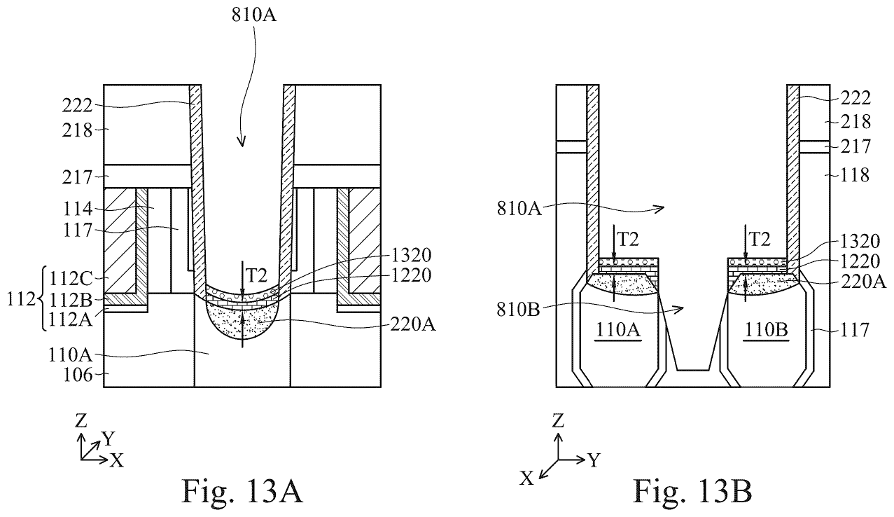

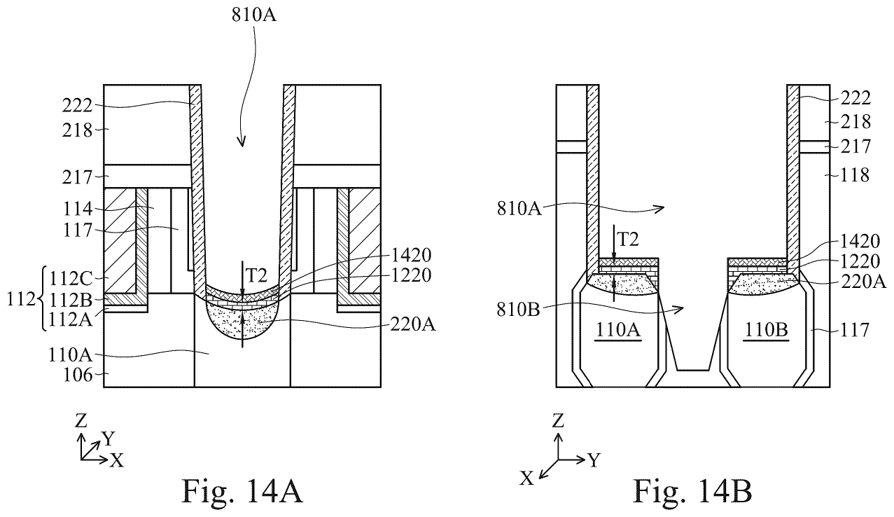

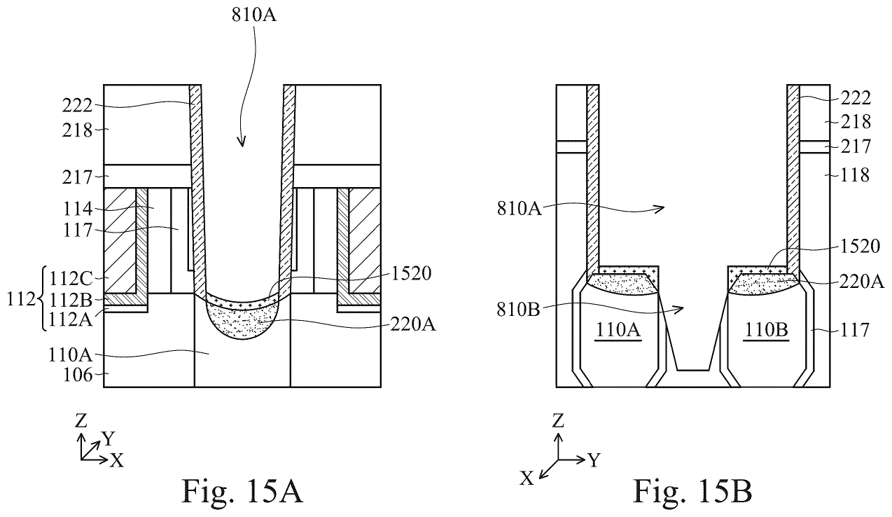

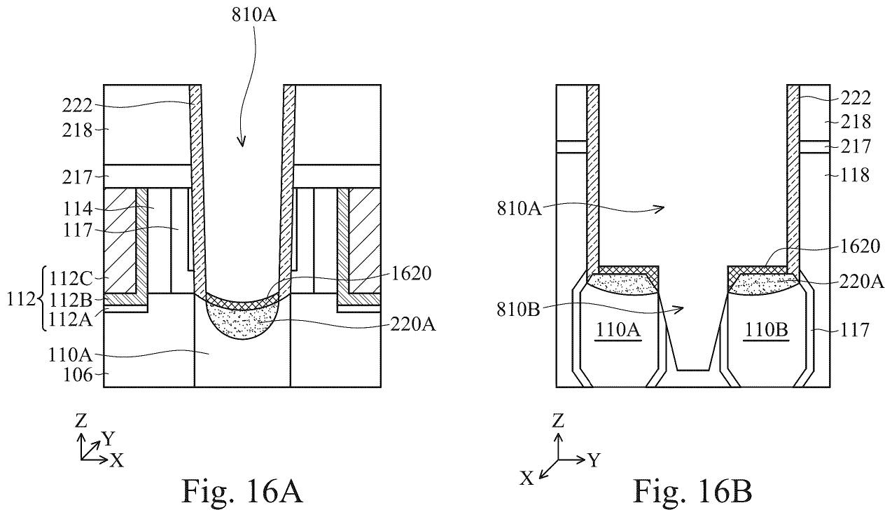

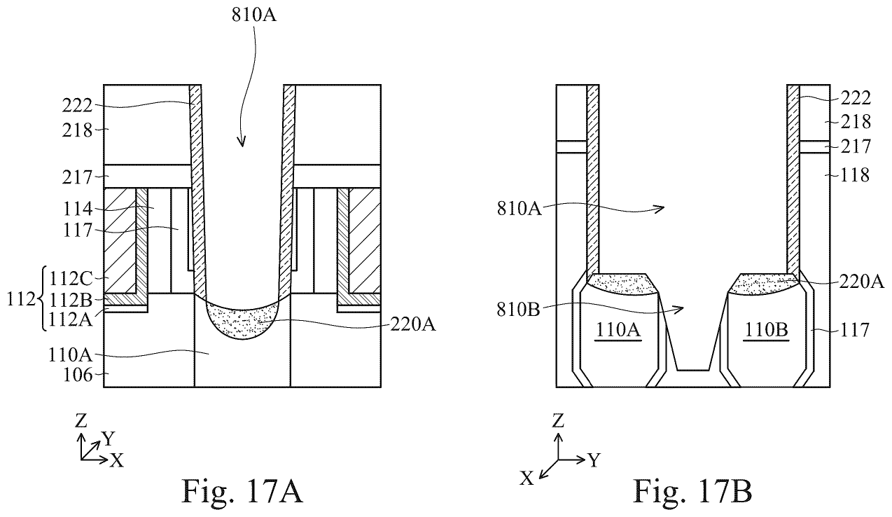

Referring to FIG. 6, in operation 625, a cleaning process is performed on the silicide layer. For example, as described with reference to FIGS. 12A-17A and 12B-17B, a cleaning process is performed on silicide layers 220A to remove native layers 1220. In some embodiments, the cleaning process can include using a non-plasma-based cleaning process, such as an atomic layer etch (ALE) process. In some embodiments, the cleaning process can include removing about one atomic layer (e.g., about 0.1 nm) of native layer 1220 in each cycle of an ALE process. In some embodiments, the cleaning process can include sequential operations of (i) exposing native layers 1220 with a thickness T1 in the structures of FIGS. 12A and 12B to a fluorine-based etching gas (e.g., tungsten hexafluoride (WF₆) or hydrogen fluoride (HF)), which etches about one atomic layer of native layer 1220 to form a byproduct layer 1320 on native layer 1220 of reduced thickness T2 and a byproduct gas (e.g., silicon fluoride (SiF)), as shown in FIGS. 13A and 13B, (ii) exposing byproduct layer 1320 to a reactant gas (e.g., boron trichloride (BC13)) to remove byproduct layer 1320 and form a byproduct layer 1420 on native layer 1220 and byproduct gases, as shown in FIGS. 14A and 14B, (iii) exposing the structures of FIGS. 14A and 14B to the fluorine-based etching gas, which etches about one atomic layer of native layer 1220 to form a byproduct layer 1520 on silicide layer 220A and a byproduct gas (e.g., SiF), as shown in FIGS. 15A and 15B, (iv) exposing byproduct layer 1520 to the reactant gas (e.g., boron trichloride (BCl₃)) to remove byproduct layer 1520 and form a byproduct layer 1620 on silicide layer 220A and byproduct gases, as shown in FIGS. 16A and 16B, and (v) removing byproduct layer 1620 to form the structures of FIGS. 17A and 17B.

In some embodiments, byproduct layers 1320 and 1520 can include tungsten oxygen nitrogen fluoride (WONF) and titanium oxygen nitrogen fluoride (TiONF) when WF₆ is used as the etching gas and native layer 1220 includes TiSiOₓN_{y}. In some embodiments, byproduct layers 1320 and 1520 can include titanium oxygen nitrogen fluoride (TiONF) when HF is used as the etching gas and native layer 1220 includes TiSiOₓN_{y}. In some embodiments, byproduct layers 1420 and 1620 can include boron oxygen nitrogen (BOₓN_{y}). In some embodiments, the byproduct gases formed along with byproduct layers 1420 and 1620 in steps (ii) and (iv) can include tungsten oxytetrachloride (WOCl₄), titanium tetrachloride (TiCl₄), boron trifluoride (BF₃), and nitrogen chloride (NClₓ).

In some embodiments, the steps of exposing native layer 1220 to the etching gas and the reactant gas can form one cycle of the ALE process. Though the cleaning process, described with reference to FIGS. 12A-17A and 12B-17B, is shown to include two cycles of the ALE process to remove native layers 1220, the cleaning process can include any number of cycles of the ALE process and the number of cycles can depend on the thickness of native layers 1220. In some embodiments, the flow rate of the etching gas and the reactant gas can be about 10 sccm to about 100 sccm. In some embodiments, the ALE process can be performed at a temperature of about 150° C. to about 300° C. and at a pressure of about 1 torr to about 10 torr.

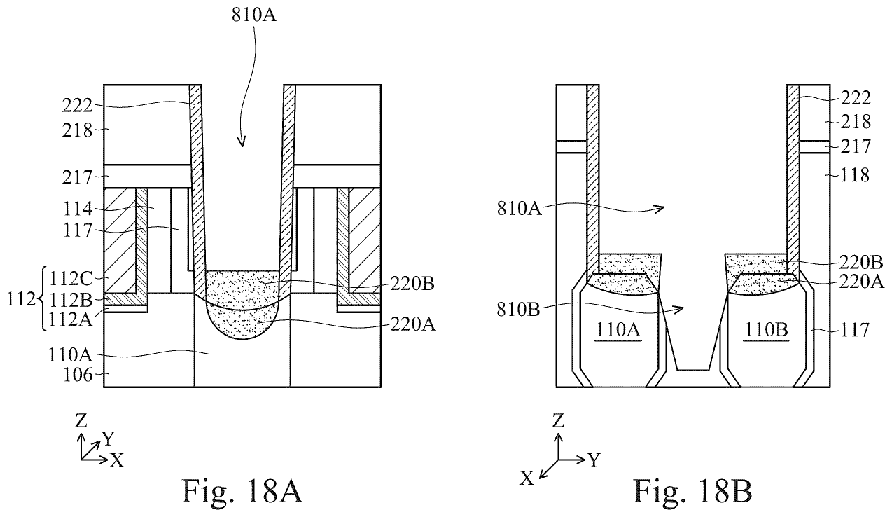

Referring to FIG. 6, in operation 630, a conductive capping layer is formed on the silicide layer. For example, as described with reference to FIGS. 18A and 18B, conductive capping layers 220B are formed on silicide layers 220A. The formation of conductive capping layer 220B can include depositing the conductive material of conductive capping layer 220B selectively on silicide layers 220A in a CVD or an ALD process. In some embodiments, the selective deposition of the conductive material can include exposing the structures of FIGS. 17A and 17B to a chlorine-based and fluorine-free metal precursor gas (e.g., tungsten pentachloride (WCl₅)) mixed with a hydrogen carrier gas in a CVD process. The use of fluorine-free metal precursor gas prevents or minimizes damages to silicide layers 220A during the selective deposition of the conductive material. In some embodiments, a gas mixture of WCl₅ and hydrogen can be used in a CVD process to selectively deposit conductive capping layer 220B having a fluorine-free W layer. The WCl₅ gas has a higher deposition selectivity for the metal of silicide layers 220A than for the dielectric materials of ESL 117, ILD layer 118, ILD layer 218, and barrier layer 222. As a result, conductive capping layer 220B with a thickness of about 1 nm to about 5 nm can be selectively formed on silicide layers 220A without forming on ESL 117, ILD layer 118, ILD layer 218, and barrier layer 222.

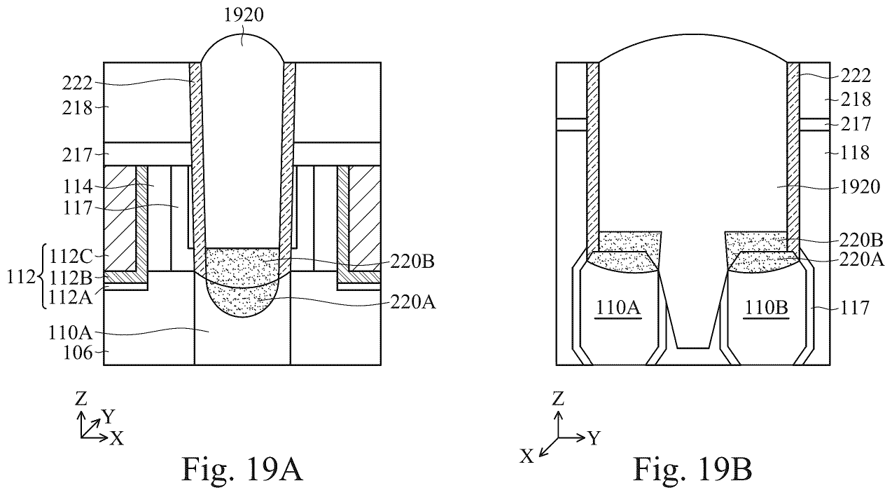

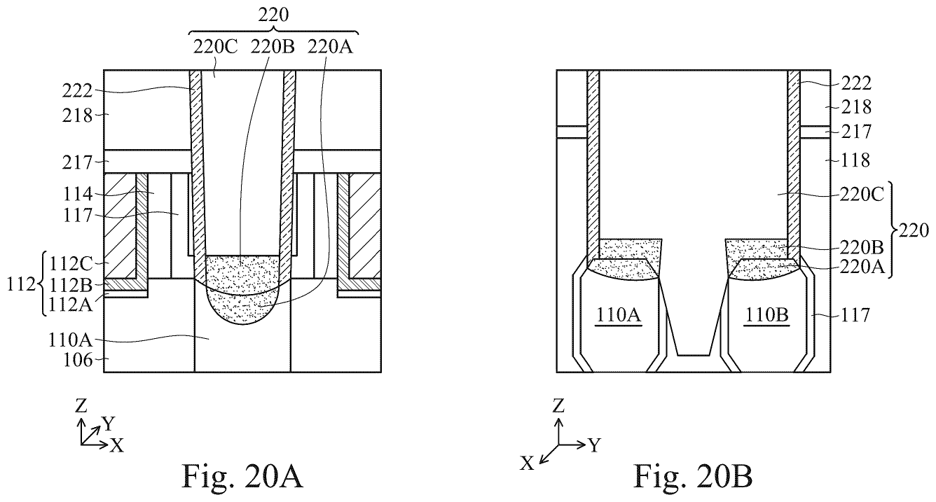

Referring to FIG. 6, in operation 635, a conductive plug is formed on the conductive capping layer. For example, as described with reference to FIGS. 19A, 19B, 20A, and 20B, conductive plug 220C is formed on conductive capping layers 220B and between S/D regions 110A and 110B. The formation of conductive plug 220C can include sequential operations of (i) depositing a conductive layer 1920 in opening 810 of FIGS. 18A and 18B in a CVD or an ALD process to form the structures of FIGS. 19A and 19B, and (ii) performing a chemical mechanical polishing (CMP) process on conductive layer 1920 to coplanarize top surfaces of conductive plug 220C, ILD layer 218, and barrier layer 222, as shown in FIGS. 20A and 20B. In some embodiments, depositing conductive layer 1920 can include exposing the structures of FIGS. 18A and 18B to a fluorine-based metal precursor gas (e.g., WF₆)) mixed with a hydrogen carrier gas in a CVD process. In some embodiments, with the use of fluorine-based metal precursor, conductive layer 1920 can have a faster deposition rate than the deposition rate of depositing the conductive material of conductive capping layer 220B using the chlorine-based and fluorine-free metal precursor gas (e.g., WCl₅).

The above discussed operations 620-635 are performed in an in-situ process (i.e., without vacuum break) to minimize the thickness of native layers 1220 formed during and/or after operation 620. Minimizing the thickness of native layers 1220 can minimize the duration of the cleaning process in operation 625, thus reducing the manufacturing cost of semiconductor device 100. The thickness of native layers 1220 can be less than the thickness of native layers formed in other semiconductor devices as silicide layers and conductive layers of contact structures in other semiconductor devices are formed in an ex-situ process. In the ex-situ process, the reaction between the silicide layers and atmospheric oxygen can form native layers thicker than native layers 1220.

In some embodiments, GAA FET 100 with the cross-sectional view of FIG. 4 can be formed using method 600 as described above with reference to FIGS. 7A-20A and 7B-20B, except (i) base structures 106 can be formed on substrate 102 and superlattice structures with nanostructured channel regions 408 and sacrificial nanostructured layers (not shown) can be formed on base structures 106 in operation 605, instead of fin structures 106 being formed on substrate 102, and (ii) GAA structures 112 can be formed on base structures 106 and around nanostructured channel regions 408 in operation 610, instead of gate structures 112 being formed on fin structures 106.

In some embodiments, GAA FET 100 with the cross-sectional view of FIG. 5 can be formed using method 600 as described above with reference to FIGS. 7A-20A and 7B-20B, except (i) base structures 106 can be formed on substrate 102 and superlattice structures with nanostructured channel regions 408 and sacrificial nanostructured layers (not shown) can be formed on base structures 106 in operation 605, instead of fin structures 106 being formed on substrate 102, (ii) GAA structures 112 can be formed on base structures 106 and around nanostructured channel regions 408 in operation 610, instead of gate structures 112 being formed on fin structures 106, and (iii) the formation of conductive plug 220C in operation 635 can be followed by sequential operations of (a) replacing substrate 102 and base structures 106 with back-side ILD layer 518 on the back sides of GAA structures 112 and S/D regions 110A and 110B, (b) forming an opening (not shown) on the back side of S/D region 110A through back-side ILD layer 518, (c) forming back-side barrier layer 522 in the opening in an operation similar to that described for forming barrier layer 222, (d) forming silicide layer 520A in the back-side opening in an operation similar to operation 620, (e) performing a cleaning process on silicide layer 520A in an operation similar to operation 625, (f) forming conductive capping layer 520B on silicide layer 520A in an operation similar to operation 630, and (g) forming conductive plug 520C on conductive capping layer 520B in an operation similar to operation 635.

The present disclosure provides example structures and methods for minimizing contact resistance between contact structures and source/drain (S/D) regions in FETs (e.g., finFET 100 and GAA FET 100). In some embodiments, a S/D region (e.g., S/D regions 110A and 110B) can be formed on a fin structure (e.g., fin structure 106) and a contact structure (e.g., contact structure 220) can be formed on the S/D region. In some embodiments, the formation of the contact structure can include forming a silicide layer (e.g., silicide layer 220A) in a contact opening on the S/D region, performing a cleaning process (e.g., ALE process) on the silicide layer, depositing a conductive capping layer (e.g., conductive capping layer 220B) on the silicide layer, and depositing a conductive plug (e.g., conductive plug 220C) on the conductive capping layer. The formation of the silicide layer, the cleaning process, the deposition of the conductive capping layer and the conductive plug can be performed in an in-situ process in a cluster tool system. The cleaning process can remove a native metal oxide layer (e.g., native metal oxide layer 1220), a native metal oxynitride layer (e.g., native metal oxynitride layer 1220), and/or oxygen atoms from a top surface of the silicide layer to reduce a concentration of oxygen atoms on the top surface of the silicide layer to less than about 5 atomic % (e.g., about zero atomic % to about 4.9 atomic %). The native metal oxide layer, the native metal oxynitride layer, and/or the oxygen atoms on the top surface of the silicide layer can be introduced due to a reaction between oxygen and the silicide layer when switching process chambers between the formation of the silicide layer and the deposition of the conductive capping layer. The presence of the native metal oxide layer, the native metal oxynitride layer, and/or the oxygen atoms at the interface between the silicide layer and the conductive capping layer can degrade the electrical conductivity between the contact structure and the S/D region. Thus, the cleaning process can minimize the contact resistance between the contact structure and the S/D region.

In some embodiments, a semiconductor device includes a substrate, first and second S/D regions disposed on the substrate, and a contact structure. The contact structure includes first and second conductive capping layers disposed on the first and second S/D regions, respectively, and a conductive plug. The conductive plug includes a first plug portion disposed on top surfaces of the first and second conductive capping layers, a second plug portion disposed between the first and second conductive capping layers, and a third plug portion disposed between the first and second S/D regions.

In some embodiments, a semiconductor device includes a S/D region, a dielectric layer disposed on a front side of the S/D region, a contact structure disposed on a back side of the S/D region. The contact structure includes a silicide layer disposed on the back side of the S/D region, a conductive capping layer disposed on the silicide layer, and a conductive plug. The conductive plug includes a first plug portion disposed on a top surface the conductive capping layer, a second plug portion disposed on a sidewall of the conductive capping layer, and a third plug portion disposed on sidewall of the S/D region.

In some embodiments, a method includes forming a S/D region on a substrate, forming a contact opening in a dielectric layer on the S/D region, forming a silicide layer on the S/D region, performing a non-plasma-based cleaning process on the silicide layer, depositing a conductive capping layer on the silicide layer at a first deposition rate, and depositing a conductive plug on the conductive capping layer at a second deposition rate faster than the first deposition rate.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
first and second source/drain (S/D) regions disposed on the substrate; and
a contact structure, comprising:
first and second conductive capping layers disposed on the first and second S/D regions, respectively; and
a conductive plug, comprising:
a first plug portion disposed on top surfaces of the first and second conductive capping layers;
a second plug portion disposed between the first and second conductive capping layers; and
a third plug portion disposed between the first and second S/D regions.

2. The semiconductor device of claim 1, wherein each of the first and second conductive capping layers comprises a fluorine-free metal layer.

3. The semiconductor device of claim 1, wherein each of the first and second conductive capping layers comprises a concentration of fluorine atoms less than about 5 atomic %.

4. The semiconductor device of claim 1, further comprising a silicide layer disposed between the first S/D region and the first conductive capping layer, wherein the first conductive capping layer comprises:
a first capping portion disposed on a top surface of the silicide layer; and
a second capping portion disposed on a sidewall of the silicide layer.

5. The semiconductor device of claim 1, wherein a bottom surface of the first conductive capping layer comprises:
a curved profile in a first cross-section of the first conductive capping layer along a first direction; and
a sloped profile in a second cross-section of the first conductive capping layer along a second direction perpendicular to the first direction.

6. The semiconductor device of claim 1, further comprising a barrier layer disposed along sidewalls of the contact structure.

7. The semiconductor device of claim 6, wherein a first sidewall of the first conductive capping layer is in contact with the barrier layer; and
wherein a second sidewall of the first conductive capping layer is in contact with the second plug portion of the conductive plug.

8. The semiconductor device of claim 1, further comprising a dielectric layer disposed between the first and second S/D regions, wherein the third plug portion of the conductive plug is disposed in the dielectric layer.

9. The semiconductor device of claim 1, wherein the conductive plug comprises a fluorine-doped metal layer.

10. The semiconductor device of claim 1, wherein each of the first and second conductive capping layers comprises a first concentration of fluorine atoms; and
wherein the conductive plug comprises a second concentration of fluorine atoms greater than the first concentration of fluorine atoms.

11. A semiconductor device, comprising:
a source/drain (S/D) region;
a dielectric layer disposed on a front side of the S/D region;
a contact structure, comprising:
a silicide layer disposed on a back side of the S/D region,
a conductive capping layer disposed on the silicide layer, and
a conductive plug, comprising:
a first plug portion disposed on a top surface of the conductive capping layer;
a second plug portion disposed on a sidewall of the conductive capping layer; and
a third plug portion disposed on a sidewall of the S/D region.

12. The semiconductor device of claim 11, wherein the conductive capping layer comprises a first concentration of fluorine atoms; and
wherein the conductive plug comprises a second concentration of fluorine atoms greater than the first concentration of fluorine atoms.

13. The semiconductor device of claim 11, further comprising an other dielectric layer surrounding the contact structure.

14. The semiconductor device of claim 11, further comprising an other contact structure disposed in the dielectric layer.

15. The semiconductor device of claim 14, wherein the conductive capping layer comprises a fluorine-free metal layer.

16. The semiconductor device of claim 14, wherein the conductive plug comprises a fluorine-doped metal layer.

17. A method, comprising:
forming a source/drain (S/D) region on a substrate;
forming a contact opening in a dielectric layer on the S/D region;
forming a silicide layer on the S/D region;
performing a non-plasma-based cleaning process on the silicide layer;
depositing a conductive capping layer on the silicide layer at a first deposition rate; and
depositing a conductive plug on the conductive capping layer at a second deposition rate faster than the first deposition rate.

18. The method of claim 17, wherein performing the non-plasma-based cleaning process comprises performing an atomic layer etch process on the silicide layer.

19. The method of claim 17, wherein performing the non-plasma-based cleaning process comprises exposing the silicide layer to a fluorine-based etching gas.

20. The method of claim 17, wherein forming the silicide layer, performing the non-plasma-based cleaning process, depositing the conductive capping layer, and depositing the conductive plug are performed in an in-situ process.
